(19) United States
(12) Patent Application Publication
(10) Pub. No.: US 2016/0211472 A1
(43) Pub. Date: Jul. 21, 2016

(54) FLEXIBLE DISPLAY DEVICE

(71) Applicant: SAMSUNG DISPLAY CO., LTD., Yongin-si (KR)

(72) Inventor: Woo Jin OH, Seoul (KR)

(21) Appl. No.: 14/875,933

(22) Filed: Oct. 6, 2015

(30) Foreign Application Priority Data
Jan. 16, 2015 (KR) 10-2015-0008217

(51) Int. Cl. H01L 51/00; H01L 27/32

(52) U.S. Cl. CPC H01L 51/0097; H01L 27/3262; H01L 27/3265

(57) ABSTRACT

A flexible display device includes a display panel having a driving circuit unit including at least two capacitors and at least two thin film transistors on a flexible substrate, each of the at least two thin film transistors including a semiconductor layer with a gate region, a drain region, and a source region on the flexible substrate, and a gate electrode on the semiconductor layer, and a display unit on the flexible substrate and connected to the driving circuit unit, wherein the display panel is partitioned into a bending area and a non-bending area, the bending area being bendable by a tensile force and a compression force, and the driving circuit unit being asymmetrically designed in the bending area and the non-bending area.

### CROSS-REFERENCE TO RELATED APPLICATION

Korean Patent Application No. 10-2015-0008217, filed on Jan. 16, 2015, in the Korean Intellectual Property Office, and entitled: “Flexible Display Device,” is incorporated by reference herein in its entirety.

### BACKGROUND

1. Field

The present disclosure relates to a flexible display device, and more particularly, to a flexible display device including a display panel which is partitioned into a bending area and a non-bending area.

2. Description of the Related Art

A flexible display device uses a flexible display panel which may be bent. When the flexible display device is bent, corresponding portions of the flexible display panel are bent. Elements of the whole area of a typical display panel are designed to have the same size and width. For example, semiconductor layers and electrodes of a thin film transistor device of the display panel are formed to have the same size and width in the whole area of the display panel, and electrodes of a capacitor are also formed to have the same size and width.

### SUMMARY

An exemplary embodiment provides a flexible display device, including a display panel having a driving circuit unit including at least two capacitors and at least two thin film transistors on a flexible substrate, each of the at least two thin film transistors including a semiconductor layer with a gate region, a drain region, and a source region on the flexible substrate, and a gate electrode on the semiconductor layer, and a display unit on the flexible substrate and connected to the driving circuit unit, wherein the display panel is partitioned into a bending area and a non-bending area, the bending area being bendable by a tensile force and a compression force, and the driving circuit unit being asymmetrically designed in the bending area and the non-bending area.

A semiconductor layer of a thin film transistor in the bending area may have a different width from a semiconductor layer of a thin film transistor in the non-bending area.

In an unbent state of the display panel, the semiconductor layer of the thin film transistor in the bending area may have a smaller width than the semiconductor layer of the thin film transistor in the non-bending area.

In a bent state of the display panel, the widths of the semiconductor layers of the thin film transistors in the bending area and the non-bending area may be substantially the same.

Source and drain regions of a thin film transistor in the bending area may have different widths from source and drain regions of a thin film transistor in the non-bending area.

In an unbent state of the display panel, the source and drain regions of the thin film transistor in the bending area may have smaller widths than the source and drain regions of the thin film transistor in the non-bending area.

In a bent state of the display panel, the widths of the drain and source regions of the thin film transistors in the bending area and the non-bending area may be substantially the same.

Each of the at least two capacitors may include a pair of capacitor electrodes with an interlayer insulating layer therebetween, and, in an unbent state of the display panel, widths of the pair of capacitor electrodes in the bending area may be smaller than that of the pair of capacitor electrodes in the non-bending area.

In a bent state of the display panel, the widths of pair of capacitor electrodes in the bending area and the non-bending area may be substantially the same.

Asize of a pixel in the bending area may be smaller than that of a pixel in the non-bending area.

The display unit may include an organic light emitting diode.

### BRIEF DESCRIPTION OF THE DRAWINGS

Features will become apparent to those of ordinary skill in the art by describing in detail exemplary embodiments with reference to the attached drawings, in which:

FIG. 1 illustrates a schematic perspective view of a display panel of a flexible display device according to an exemplary embodiment.

FIG. 2 illustrates a schematic diagram of a bent state of the display panel of the flexible display device according to an exemplary embodiment.

FIG. 3 illustrates an equivalent circuit diagram of a flexible display device according to an exemplary embodiment.

FIG. 4 illustrates a layout view of a pixel structure of the display panel of a flexible display device according to an exemplary embodiment.

FIG. 5 illustrates a cross-sectional view along line V-V of FIG. 4.

FIG. 6 illustrates schematic diagrams of widths of a thin film transistor in an unbent state in a non-bending area and a bending area according to an exemplary embodiment.

FIG. 7 illustrates schematic diagrams of the widths of a thin film transistor in a bent state in the non-bending area and the bending area according to an exemplary embodiment.

FIG. 8 illustrates schematic diagrams of a change in a length of a bending area before and after the display panel is bent according to an exemplary embodiment.

FIG. 9 illustrates schematic diagrams of widths of a thin film transistor in an unbent state in a non-bending area and a bending area according to another exemplary embodiment.

FIG. 10 illustrates schematic diagrams of the widths of a thin film transistor in a bent state in the non-bending area and the bending area according to another exemplary embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Therefore, the exemplary embodiments are not limited to a specific form of the illustrated region and, for example, may also include a form changed by manufacturing.

It will also be understood that when a layer or element is referred to as being “on” or “over” another layer or substrate, it can be directly on or over the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

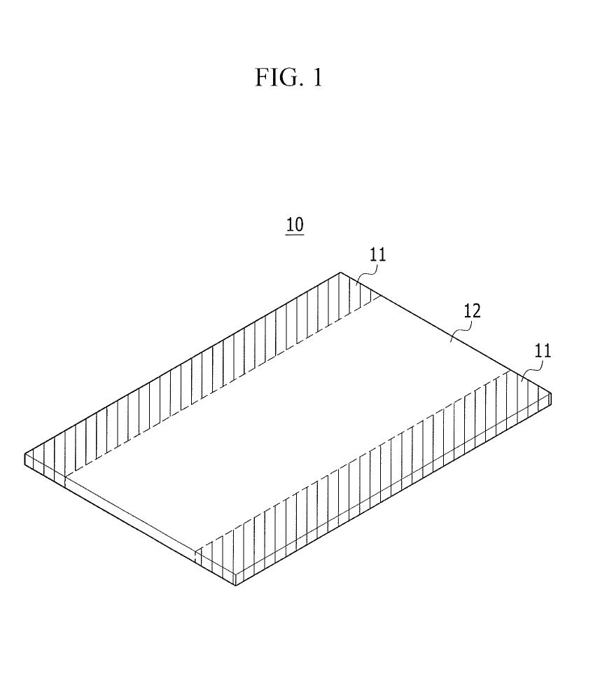

Hereinafter, a flexible display device according to an exemplary embodiment will be described with reference to FIGS. 1 to 5.

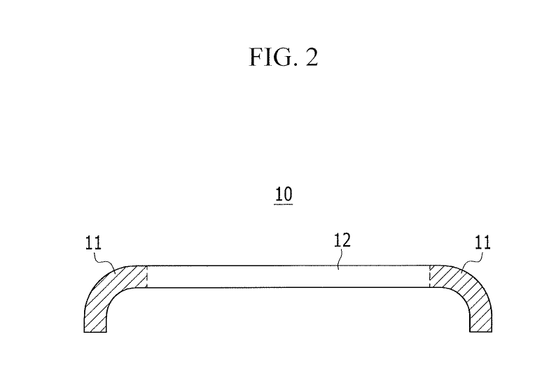

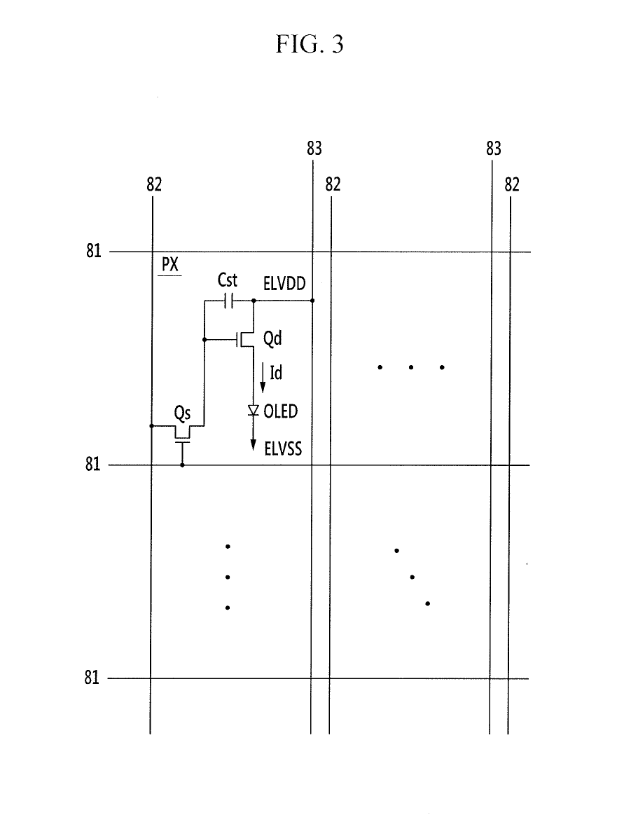

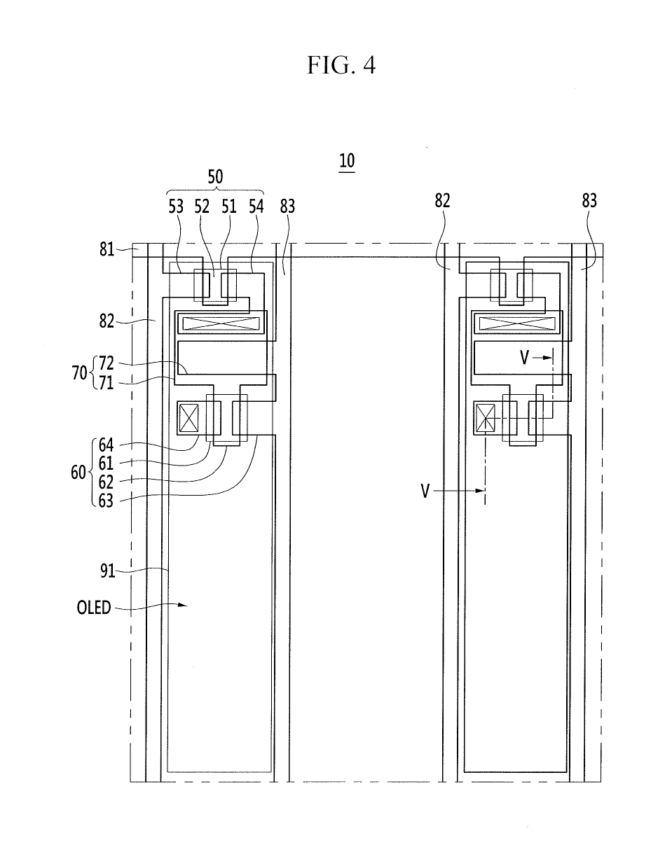

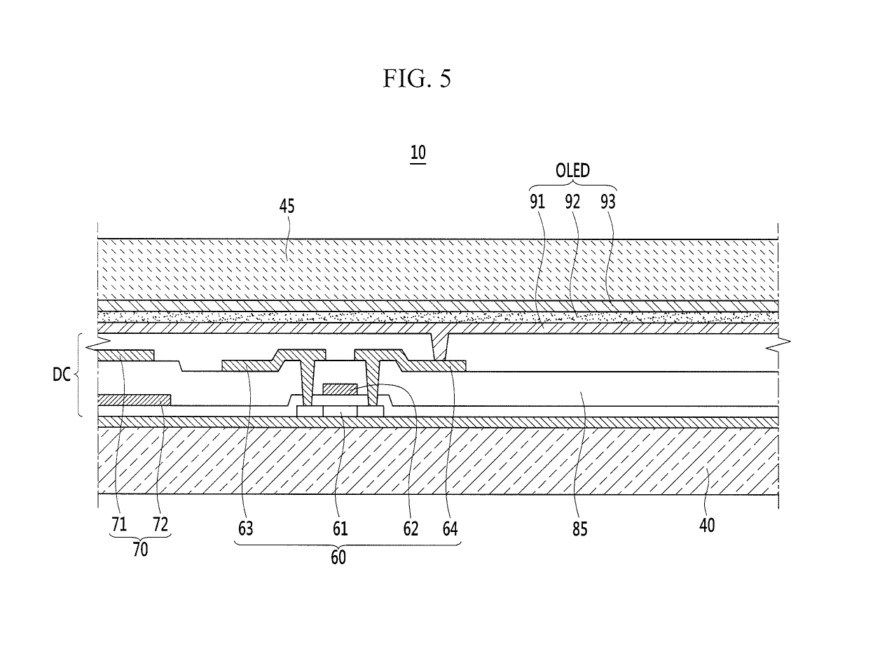

FIG. 1 illustrates a perspective view schematically illustrating a display panel of a flexible display device according to an exemplary embodiment, and FIG. 2 illustrates a diagram schematically illustrating a bent state of the display panel of the flexible display device according to the exemplary embodiment. FIG. 3 illustrates an equivalent circuit diagram of the flexible display device according to the exemplary embodiment, FIG. 4 illustrates a layout view illustrating a pixel structure of the display panel of the flexible display device according to the exemplary embodiment, and FIG. 5 illustrates a cross-sectional along line V-V of FIG. 4.

Referring to FIGS. 1-5, a flexible display device may include a display panel 10, which includes a flexible substrate 40, at least one thin film transistor 60 formed on the flexible substrate 40, a driving circuit unit including at least one capacitor 70, and at least one display unit OLED, e.g., an organic light emitting diode OLED, formed on the flexible substrate 40 and connected to the driving circuit unit. As illustrated in FIGS. 1-2, the display panel 10 is partitioned into a bending area 11 and a non-bending area 12.

In detail, referring to FIGS. 1-2, the bending area 11 of the display panel 10 may be formed at one side or both sides of an edge portion of the display panel 10, and is deformed, e.g., bent or curved, by being applied with a tensile force and a compression force when being bent (FIG. 2). The non-bending area 12 may be formed at a portion other than the edge portion of the display panel 10, e.g., in a central portion of the display panel 10. The non-bending area 12 may be an area other than the bending area 11, and may be an area in which an original, e.g., unbent, shape of the display panel 10 is kept when the display panel 10 is bent. For example, in a state in which the display panel 10 is bent, tensile force is applied to an upper surface of the display panel 10, so an upper surface of the display panel 10 extends further than that of the original, e.g., unbent, display panel 10.

As illustrated in FIG. 5, the display panel 10 may include a driving circuit unit, which is formed on the flexible substrate 40, and a thin film encapsulation layer 45, which encapsulates the organic light emitting diode OLED. For example, the flexible substrate 40 may be made of a flexible plastic material but the exemplary embodiment is not limited thereto. In another example, the flexible substrate 40 may also be formed as a metallic substrate made of, e.g., stainless steel, and the like, and other various flexible materials may be used. In yet another example, the flexible substrate 40 may be made of a plastic material having excellent heat resistance and durability, e.g., polyethylene ether phthalate, polyethylene naphtalate, polycarbonate, polyarylate, polyetherimide, polyether sulfone, polyimide, a low temperature polysilicon (LIPS) layer, etc.

The driving circuit unit includes the thin film transistor 60 and drives the organic light emitting diode OLED. The organic light emitting diode OLED is connected to the driving circuit unit and emits light depending on a driving signal transferred from the driving circuit unit to display an image. The organic light emitting diode OLED and the driving circuit unit may be formed to have various structures within a range which may be easily modified by those skilled in the art. The thin film encapsulation layer 45 is formed on the flexible substrate 40 to cover the organic light emitting diode OLED and the driving circuit unit, and may be made of a plurality of inorganic layers or may be made of a mixture of inorganic layers.

According to example embodiments, the driving circuit unit may be asymmetrically designed in the bending area 11 and the non-bending area 12. In detail, when the bending area 11 of the display panel 10 is bent, a length in the bending area 11 extends and widths of components forming devices, e.g., the thin film transistor 60 and the capacitor 70, of the driving circuit unit which are positioned in the bending area 11 are increased accordingly. Therefore, when widths of the devices are identical in the bending area 11 and the non-bending area 12 in an unbent state of the display panel 10, the widths of the devices are changed in a bent state of the display panel 10, i.e., widths of the devices in the bending area 11 become larger than those in the non-bending area 12, thereby changing characteristics of the devices depending on their positions to cause a problem of reliability, e.g., non-uniform performance among same devices. Thus, according to example embodiments, the driving circuit unit, e.g., the pixel PX, the thin film transistor 60, and the capacitor 70, may be asymmetrically designed in the bending area 11 and the non-bending area 12.

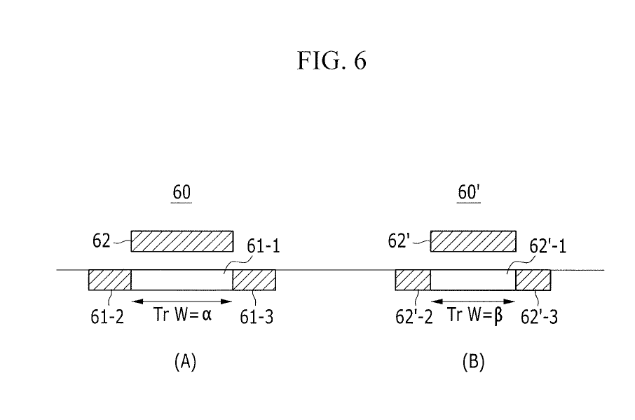

In detail, as illustrated in FIG. 6, the width of the semiconductor layer 61 of the thin film transistor 60 in the bending area 11 may be formed to be smaller than that of the semiconductor layer in the non-bending area 12. The thin film transistor 60 includes a semiconductor layer 61 (FIG. 5) which includes a drain region 61-3, a gate region 61-1, and a source region 61-2, and a gate electrode 62 formed on the semiconductor layer 61. The width, i.e., a distance measured in parallel to an upper surface of the flexible substrate 40 along a bending direction, of the semiconductor layer 61 in the bending area 11 may be formed to be smaller than that of the semiconductor layer in the non-bending area 12, as will be described in more detail below with reference to FIG. 6. Further, widths of the drain region 61-3 and the source region 61-2 in the bending area 11 may be formed to be smaller than those of the drain region and the source region in the non-bending area 12. Therefore, the display panel 10 with the asymmetrical design in an unbent state, i.e., with the non-uniform widths in an unbent state described above, exhibits the semiconductor layer 61, the drain region 61-3, and the source region 61-2 in the bending area 11 and the non-bending area 12 with same widths in a bent state due to stretching of devices in the bending area 11.

Similarly, capacitor electrodes 71 and 72 of the capacitor 70 (FIG. 5) may be formed to have different sizes in the bending area 11 and the non-bending area 12. The capacitor 70 may include a pair of capacitor electrodes 71 and 72, having an interlayer insulating layer 85, which is a dielectric material, disposed therebetween. Widths of the capacitor electrodes 71 and 72 in the bending area 11 may be formed to be smaller than those of the capacitor electrodes in the non-bending area 12. Therefore, when the display panel 10 is bent, widths of the capacitor electrodes 71 and 72 in the bending area 11 extend to equal widths of the capacitor electrodes in the non-bending area 12, thereby providing capacitors with the same size in a bent state of the display panel 10.

Referring to FIG. 3, the flexible display device includes a plurality of signal lines 81, 82, and 83, and a plurality of pixels PXs which are connected thereto and arranged in an approximate a matrix form. The signal lines includes a plurality of gate lines 81 which transfer scan signals (or gate signals), a plurality of data lines 82 which transfer data signals, and a plurality of driving voltage lines 83 which transfer a driving voltage. The gate lines 81 approximately extend in a row direction and are approximately parallel with each other, and the data lines 82 and the driving voltage lines 83 approximately extend in a column direction and are approximately parallel with each other.

Each pixel PX may include a switching thin film transistor Qs, a driving thin film transistor Qd, a storage capacitor Cst, and the organic light emitting diode OLED.

The switching thin film transistor Qs includes a control terminal, an input terminal, and an output terminal. in which the control terminal is connected to the gate line 81, the input terminal is connected to the data line 82, and the output terminal is connected to the driving thin film transistor Qd. The switching thin film transistor Qs transfers the data signal applied to the data line 82 to the driving thin film transistor Qd in response to the scan signal applied to the gate line 81.

The driving thin film transistor Qd includes a control terminal, an input terminal, and an output terminal, in which the control terminal is connected to the switching thin film transistor Qs, the input terminal is connected to the driving voltage line 83, and the output terminal is connected to the organic light emitting diode OLED. The driving thin film transistor Qd transfers an output current Id of which a magnitude varies depending on a voltage applied between the control terminal and the output terminal.

The storage capacitor Cst is connected between the control terminal and the input terminal of the driving thin film transistor Qd. The storage capacitor Cst charges the data signal applied to the control terminal of the driving thin film transistor Qd and maintains the charged data signal even after the switching thin film transistor Qs is turned off.

The organic light emitting diode OLED has an anode connected to the output terminal of the driving thin film transistor Qd and a cathode connected to a common voltage (ELVSS). The organic light emitting diode OLED emits light of which the intensity varies depending on the output current Id of the driving thin film transistor Qd to display an image.

The switching thin film transistor Qs and the driving thin film transistor Qd may be n-channel field effect transistors (FETs). However, at least one of the switching thin film transistor Qs and the driving thin film transistor Qd may be a p-channel electric field effect transistor. Further, a connection relationship among the thin film transistors Qs and Qd, the capacitor Cst, and the organic light emitting diode OLED may be changed.

Referring to FIGS. 4 and 5, the flexible display panel 10 may include pixel circuits DCs and the organic light emitting diode OLED which are formed in each pixel PX. The pixel circuit DC basically includes the thin film transistor 60 and the capacitor 70. Further, the flexible display panel 10 includes the gate line 81, which is disposed along one direction, and the data line 82 and the driving voltage line 83 which intersect the gate line 81, being insulated therefrom.

Here, one pixel PX may be defined by a boundary between the gate line 81 and the data line 82 and the driving voltage line 83, but is not limited thereto. The pixel PX refers to a basic unit displaying an image, and the flexible display panel 10 uses the plurality of pixels PXs to display an image.

A structure of the flexible display panel 10 is not limited to the illustrated example. For example, the flexible display panel 10 may include at least three thin film transistors and at least two capacitors, and may be formed in various structures by further including a separate wiring.

The organic light emitting diode OLED includes a pixel electrode 91, an organic emission layer 92, and a common electrode 93. Any one of the pixel electrode 91 and the common electrode 93 is a hole injection electrode and the other thereof is an electron injection electrode. Electrons and holes are injected from the pixel electrode 91 and the common electrode 93 into the organic emission layer 92, and when excitions, in which holes and electrons are combined, fall from an excited state to a ground state, light is emitted.

The pixel electrode 91 may be made of metal having high reflectance, and the common electrode 93 may be formed of a transparent conductive layer. In this case, light from the organic emission layer 92 is reflected by the pixel electrode 91 and transmits through the common electrode 93 and the thin film encapsulation layer 45 to be emitted to the outside.

The capacitor 70 includes the pair of capacitor electrodes 71 and 72, having the interlayer insulating layer 85, which is a dielectric material, disposed therebetween. Capacitance is determined by a charge charged in the capacitor 70, and a voltage between the two capacitor electrodes 71 and 72.

The driving thin film transistor 60 applies driving power for emitting the organic emission layer 92 of the selected pixel to the pixel electrode 91. The driving gate electrode 62 is connected to the capacitor electrode 71. A source electrode 63 and the capacitor electrode 72 are connected to the driving voltage line 83. A drain electrode 64 is connected to the pixel electrode 91 of the organic light emitting diode OLED through a contact hole.

The thin film encapsulation layer 45 may have a structure in which at least one organic layer and at least one inorganic layer are alternately stacked one by one. The organic layer may be formed of polymer, e.g.. a single layer or a stacked layer formed of any one of polyethylene terephthalate, polyimide, polycarbonate, epoxy, polyethylene, and polyacrylate. The inorganic layer may be, e.g., a single layer or a stacked layer including metal oxide or metal nitride. For example, the inorganic layer may include any one of SiN_{X}, Al₂O₃, SiO₂, and TiO₂. Among the thin film encapsulation layer 45, a top layer, which is exposed to the outside, may be formed of an inorganic layer to prevent humidity from permeating into the organic light emitting diode OLED.

According to an exemplary embodiment, the pixel PX of the display unit illustrated in FIGS. 3 to 5 may be formed to have different sizes in the bending area 11 and the non-bending area 12. That is, the size of the pixel in the bending area 11 may be formed to be smaller than that of the pixel PX in the non-bending area 12.

Further, the thin film transistor 60 may be formed to have different sizes in the bending area 11 and the non-bending area 12. To prevent the change in characteristics of the devices of the thin film transistor 60 in the bending area 11 relative to those in the non-bending area 12, i.e., when the bending area 11 is deformed by being applied with a tensile force and a compression force when the display panel 10 is bent, the size of the devices of the thin film transistor 60 may be minimized. Further, the thin film transistor 60 may be formed by being divided into at least two in the bending area 11.

Similarly, the capacitor electrodes 71 and 72 of the capacitor 70 illustrated in FIGS. 3 to 5 may each be formed to have different sizes in the bending area 11 and the non-bending area 12. When the display panel 10 is bent, a distance between the capacitor electrodes 71 and 72 is changed and thus the charged amount of the capacitor 70 is not constant but is changed. Therefore, the widths of the capacitor electrodes 71 and 72 in the bending area 11 may be formed to be smaller than those of the capacitor electrodes 71 and 72 in the non-bending area 12, i.e., to account for the deformation during bending. Further, the widths and the lengths of the capacitor electrodes 71 and 72 are subdivided and thus the capacitor 70 is formed by being divided into at least two in the bending area 11, thereby minimizing the change in the charged amount.

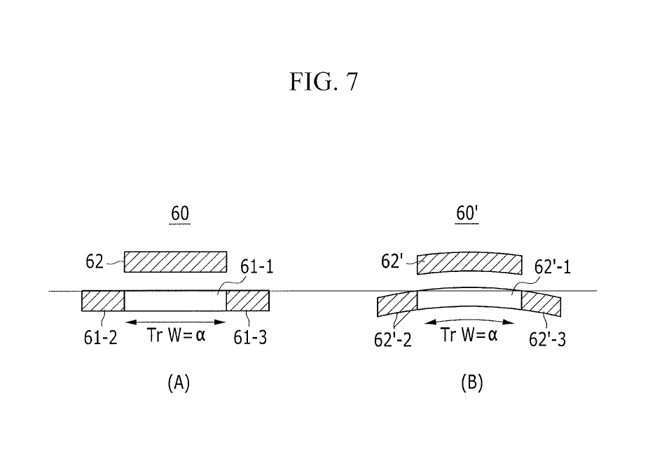

FIG. 6 illustrates diagrams of different widths of the thin film transistor 60 in the non-bending area 12 and the bending area 11 in an unbent state. FIG. 7 illustrates diagrams of the widths of the thin film transistor 60 in the non-bending area 12 and the bending area 11 after bending. Diagram (A) in each of FIGS. 6-7 refers to the non-bending area 12, and diagram (B) in each of FIGS. 6-7 refers to the bending area 11.

Referring to FIG. 6, in diagram (A), the semiconductor layer of the thin film transistor 60 in the non-bending region 12 includes the drain region 61-3, the gate region 61-1, and the source region 61-2. The gate electrode 62 is formed on the semiconductor layer, corresponding to the gate region 61-1. The gate region 61-1 in the non-bending area 12 has a constant width (W) α.

In diagram (B), a semiconductor layer of the thin film transistor 60′ in the bending area 11 includes a drain region 62-3′, a gate region 62-1′, and the source region 62-2′, and a gate electrode 62 formed on the semiconductor layer, corresponding to the gate region 62-1′. Before the display panel 10 is bent, a width (W) β of the gate region 62′-1 in the bending area 11 is formed to be smaller than the width (W) α of the gate region 61-1 in the non-bending area 12.

Further, referring to FIG. 7, after the display panel 10 is bent, as illustrated in diagram (B) of FIG. 7, the width of the gate region 62′-1 in the bending area 11 increases. Therefore, after bending, the width (W) β of the gate region 62′-1 in the bending area 11 equals the width (W) α of the gate region 61-1 in the non-bending area 12.

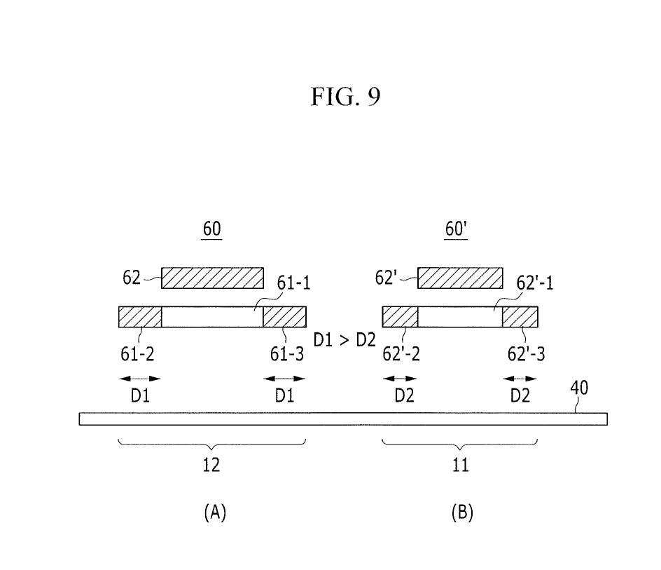

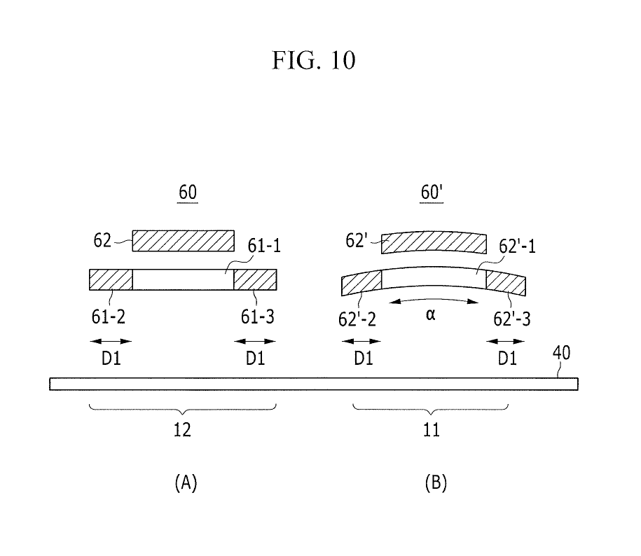

FIGS. 6 and 7 illustrate an example in which only the widths of the gate regions 61-1 and 62′-1 of the semiconductor layers of the thin film transistors 60 and 60′ are designed to be different in the bending area 11 and the non-bending 12 in an unbent state. Further, referring to FIGS. 9 and 10, widths of the source regions 61-2 and 62′-2, the drain regions 61-3 and 62′-3, the gate electrodes 62 and 62′, the source electrode 63, and the drain electrode 64 may be also designed to be different in the bending area 11 and the non-bending area 12 in the unbent state of the display panel 10.

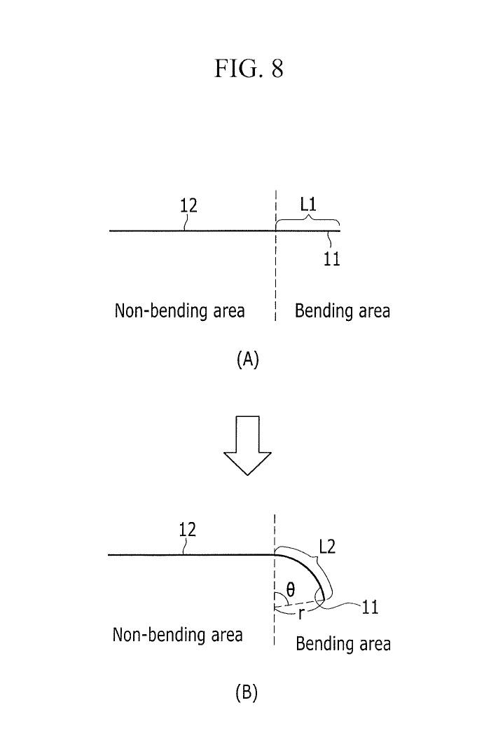

FIG. 8 illustrates diagram schematically illustrating a change in a length before and after the display panel 10 is bent.

Referring to FIG. 8, the length of the display panel 10 in the non-bending area 12 is the same in the unbent state and the bent state. However, the length of the display panel 10 in the bending area 11 is different in the two states. As illustrated in diagram (A) of FIG. 8, the bending area 11 may have a flat shape with a length L1 in the unbent state of the display panel 10. In contrast, as illustrated in diagram (B) of FIG. 8, the bending area 11 has a curved shape with a length L2 in the bent shape. The curved shape of the bending area 11 in a bent state may have a curvature radius of r and a bent angle θ.

When the length of the bending area 11 before the display panel 10 is bent is L1 and a curvature radius of the bending portion after the display panel 10 is bent is r, the length L2 of the bending area 11 after the display panel 10 is bent may be represented by the following Equation 1.

L2=r×θ Equation 1

Further, an extending ratio of L2 to length L1 may be represented by the following Equation 2.

$$\frac{L 2}{L 1} = ( \frac{r \times θ}{L 1} ) \qquad Equation 2$$

Therefore, a width of the thin film transistor 60′ in the bending area 11 extends by (r×θ)/L1 after the bending. Therefore, at the time of the first design, the width of the thin film transistor 60′ is designed to be smaller by (r×θ)/L1.

For example, when the width of the thin film transistor 60′ to be kept after the bending is X, the width L1 of the thin film transistor 60′ in the bending area 11 before the bending is represented by the following Equation 3.

$$L 1 = X \times ( \frac{L 1}{r \times θ} ) \qquad Equation 3$$

When the bending area 11 of the thin film transistor 60′ designed to have the width is bent in the state in which the curvature radius is r and the angle is θ, the width L2 of the bending area of the thin film transistor 60′ after the bending is represented by the following Equation 4.

$$L 2 = L 1 \times ( \frac{r \times θ}{L 1} ) = X \times ( \frac{L 1}{r \times θ} ) \times ( \frac{r \times θ}{L 1} ) = X \qquad Equation 4$$

That is, L2 is equal to X and has the width of the desired thin film transistor 60′ after the bending.

By way of summation and review, when the flexible display device is bent, in the flexible display panel, an inner side of a bent portion is contracted by being applied with a compression force and an outer side of the bent portion is expanded by being applied with a tensile force. Therefore, the sizes and widths of the thin film transistors, signal wires, capacitors, etc., in a portion of the display panel which is expanded by bending are more expanded than those in a portion which is not bent (or not expanded). As such, when the display panel is bent, characteristics of the thin film transistor (TFT) devices and characteristics of the capacitors in the bent portions of the display panel may be changed due to their corresponding expansion of sizes and widths. Therefore, the flexible display panel may be easily damaged and durability thereof may deteriorate.

In contrast, example embodiments provide a flexible display device having constantly maintained device characteristics when being bent, by differently designing sizes of devices in a bending area and a non-bending area of a display panel. That is, according to an exemplary embodiment, it is possible to improve the durability of the display device by making the sizes and widths of its devices, e.g., the thin film transistor, the capacitor, and the like, identically kept in the bending area and the non-bending area when the flexible display device is bent so as to identically keep the characteristics of the thin film transistor and the capacitor.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A flexible display device, comprising:
a display panel including:
a driving circuit unit including at least two capacitors and at least two thin film transistors on a flexible substrate, each of the at least two thin film transistors including:
a semiconductor layer with a gate region, a drain region, and a source region on the flexible substrate, and
a gate electrode on the semiconductor layer, and
a display unit on the flexible substrate and connected to the driving circuit unit,
wherein the display panel is partitioned into a bending area and a non-bending area, the bending area being bendable by a tensile force and a compression force, and the driving circuit unit being asymmetrically designed in the bending area and the non-bending area.

2. The flexible display device as claimed in claim 1, wherein a semiconductor layer of a thin film transistor in the bending area has a different width from a semiconductor layer of a thin film transistor in the non-bending area.

3. The flexible display device as claimed in claim 2, wherein, in an unbent state of the display panel, the semiconductor layer of the thin film transistor in the bending area has a smaller width than the semiconductor layer of the thin film transistor in the non-bending area.

4. The flexible display device as claimed in claim 3, wherein, in a bent state of the display panel, the widths of the semiconductor layers of the thin film transistors in the bending area and the non-bending area are substantially the same.

5. The flexible display device as claimed in claim 1, wherein source and drain regions of a thin film transistor in the bending area have different widths from source and drain regions of a thin film transistor in the non-bending area.

6. The flexible display device as claimed in claim 5, wherein, in an unbent state of the display panel, the source and drain regions of the thin film transistor in the bending area have smaller widths than the source and drain regions of the thin film transistor in the non-bending area.

7. The flexible display device as claimed in claim 6, wherein, in a bent state of the display panel, the widths of the drain and source regions of the thin film transistors in the bending area and the non-bending area are substantially the same.

8. The flexible display device as claimed in claim 1, wherein:
each of the at least two capacitors includes a pair of capacitor electrodes with an interlayer insulating layer therebetween, and
in an unbent state of the display panel, widths of the pair of capacitor electrodes in the bending area is smaller than that of the pair of capacitor electrodes in the non-bending area.

9. The flexible display device as claimed in claim 8, wherein, in a bent state of the display panel, the widths of pair of capacitor electrodes in the bending area and the non-bending area are substantially the same.

10. The flexible display device as claimed in claim 1, wherein a size of a pixel in the bending area is smaller than that of a pixel in the non-bending area.

11. The flexible display device as claimed in claim 1, wherein the display unit includes an organic light emitting diode.
